(19) United States
(12) Patent Application Publication
(10) Pub. No.: US 2026/0371801 A1
(43) Pub. Date: Nov. 19, 2026

(54) TWO-SIDED ETCHED LIGHT GENERATING STRUCTURE AND OPTOELECTRONIC DEVICE

(71) Applicant: ams-OSRAM International GmbH, Regensburg (DE)

(72) Inventors: Anna Kasprzak-Zablocka, Donaustauf (DE); Martin Hetzl, Painten (DE)

(21) Appl. No.: 19/515,388

(22) PCT Filed: Aug. 26, 2024
(86) PCT No.: PCT/EP2024/073842

§ 371 Date: Feb. 27, 2026

(30) Foreign Application Priority Data
Aug. 30, 2023 (DE) 102023123372.6

(51) Int. Cl. H10H 20/856; H10H 20/01; H10H 20/821; H10H 20/831; H10H 20/832

(52) U.S. Cl. CPC H10H 20/856; H10H 20/017; H10H 20/032; H10H 20/0363; H10H 20/821; H10H 20/8314; H10H 20/835

(57) ABSTRACT

In an embodiment a light generating structure includes a semiconductor layer stack having a light emitting surface, a bottom surface opposite the light emitting surface and first side wall portions extending from the bottom surface in a direction of the light emitting surface, wherein the first side wall portions comprise portions of the first layer, the second layer and the active region, a regrowth layer covering at least the bottom surface and the first side wall portions, a bottom contact element arranged on the regrowth layer opposite the first layer, and second side wall portions different from the first side wall portions extending from the light emitting surface into a direction of the bottom surface, the second side wall portions comprising at least portions of the regrowth layer, wherein the first side wall portions and the second side wall portions are inclined into different directions.

### CROSS-REFERENCE TO RELATED APPLICATIONS

This patent application is a national phase filing under section 371 of PCT/EP2024/073842, filed Aug. 26, 2024, which claims priority from German patent application DE 10 2023 123 372.6 filed on Aug. 30, 2023, each of which is incorporated herein by reference in its entirety.

### TECHNICAL FIELD

The present invention concerns a light generating structure, an optoelectronic device comprising the light generating structure as well as a method for manufacturing the optoelectronic device.

### BACKGROUND

Small light emitting components, in particular red emitting μLEDs fabricated from InGaAlP, require specific surface passivation techniques, e.g., regrowth, in order to make the μLED efficient. In this context, both regrowth and mesa structuring are to date done from the same side of the semiconductor layer stack of the μLEDs, before transferring the μLEDs to a carrier substrate. After rebonding the μLEDs from its growth substrate to its target substrate the mesa etched structures are embedded in an isolation and metallization layer. In addition, electrical contacts are realized around the mesa etched structures to inject a current into the semiconductor layer stack of the μLEDs. However, this requires a residual large-scale semiconductor layer of the semiconductor layer stack in order to sufficiently spread the current into the semiconductor layer stack. This on the other hand can however lead to optical crosstalk of light through the residual large-scale semiconductor layer to neighbouring μLEDs due to insufficient light outcoupling in the actual light emitting direction of the μLEDs.

### SUMMARY

Embodiments provide an enhanced light emitting component, which overcomes at least one of the aforementioned downsides.

An embodiment of the invention is to structure the semiconductor layer stack of a light generating structure, in particular μLED, after the transfer of a pre-structured array of light generating structures on a target substrate in a way, that a subsequently applied reflective grid lies deeper within the overall structure, forming a parabolic mirror-like forward outcoupling structure together with a bottom contact element of the light emitting component. This leads to an overall increased outcoupling efficiency, as well as a focusing of light into a smaller solid angle. The latter is an important requirement for projection applications, such as AR/VR. In addition, a step of mesa structuring the semiconductor layer stack of the light emitting component from two different sides of the semiconductor layer stack, isolation and top contact deposition onto the semiconductor layer stack can enhance internal quantum efficiency (IQE)/reduce nonradiative recombination due to current crowding towards the centre of the semiconductor layer stack from both sides.

According to a first embodiment a light generating structure is provided. The light generating structure can in particular be part of an optoelectronic device and can in particular be in form of a small LED or μLED. The light generating structure can in particular be configured to emit light of a desired wavelength or wavelength range when electrically powered. The light generating structure comprises a semiconductor layer stack of at least a first layer of a first conductivity type, a second layer of a second conductivity type as well as an active region between the first and second layer. The semiconductor layer stack comprises a light emitting surface, a bottom surface opposite the light emitting surface and first side wall portions extending from the bottom surface into the direction of the light emitting surface. The first side wall portions comprise portions of the first layer, the second layer and the active region.

The light generating structure further comprises a regrowth layer covering at least the bottom surface and the first side wall portions and a bottom contact element arranged on the regrowth layer opposite the first layer.

The light generating structure on the other hand comprises second side wall portions different from the first side wall portions extending from the light emitting surface into the direction of the bottom surface, wherein the second side wall portions comprise at least portions of the regrowth layer.

According to some embodiments, the second side wall portions comprise in addition to portions of the regrowth layer portions of the second layer.

The first and second side wall portions can result from each an etching step in particular mesa etching step. The first side wall portions can in particular result from a first mesa etching step of the semiconductor layer stack from a first side of the semiconductor layer stack whereas the second side wall portions can in particular result from a second mesa etching step of at least the regrowth layer and optionally also the second layer of the semiconductor layer stack from a second side of the semiconductor layer stack different to the first side. By means of these two mesa etching steps in combination with a respective arrangement of contact elements, a particularly advantageous structure can be achieved be means of which the IQE of the light generating structure can be increased by for example reducing nonradiative recombination due to current crowding towards the centre of the semiconductor layer stack from both sides.

The term side wall portions shall in this regard be understood as at least portions of the side walls of the respective structure being etched. The respective structure being etched resulting in the first side wall portions can in particular be only the semiconductor layer stack, whereas the respective structure being etched resulting in the second side wall portions can in particular be not only the semiconductor layer stack but a combination of the semiconductor layer stack, the regrowth layer and the bottom contact element. Hence even if both called side wall portions, the first and second side wall portions are not limited to side wall portions of the same body but can concern different bodies and can thus at least partially overlap or lie within each other.

According to some embodiments, adjacent first side wall portions and second side wall portions are laterally distant from each other. In particular, adjacent first side wall portions and second side wall portions are shifted towards each other laterally and are not contiguous.

This can in particular result from the first side wall portions being side wall portions of the semiconductor layer stack and the second side wall portions being side wall portions of not only the semiconductor layer stack but a combination of the semiconductor layer stack with the regrowth layer. In addition, the lateral shift can result from two different etching steps from two different sides of the semiconductor layer stack with different sized etched surfaces and cross sections resulting from the etching.

According to some embodiments, the first side wall portions and/or the second side wall portions are inclined. In particular, the first side wall portions can result from a first mesa etching step of the semiconductor layer stack from a first side of the semiconductor layer stack whereas the second side wall portions can result from a second mesa etching step of at least the regrowth layer and optionally also the second layer of the semiconductor layer stack from a second side of the semiconductor layer stack different to the first side. Due to the mesa etching, the resulting side wall portions can be inclined with respect to a perpendicular of the light emitting surface or bottom surface. The mesa etching can in particular leave a truncated pyramid or truncated cone in each case, the outer surfaces of which form the first and second side wall portions at least in places. In particular, the mesa etching can leave a truncated pyramid or truncated cone of different sizes stacked on top of each other, the outer surfaces of which form the inclined and laterally distant from each other first and second side wall portions at least in places.

According to some embodiments, the first side wall portions and the second side wall portions are inclined into different directions. In particular, adjacent side wall portions may be inclined in different directions so that they are substantially mirror-inverted or extend in substantially mirrored directions. The resulting structure may in particular be diamond-shaped or kite-shaped in cross-section, with the upper and lower ends in particular being flattened. In other words, the resulting structure can be formed in cross-section in particular in the form of two trapezoids arranged one on top of the other, the longer base sides of the trapezoids being adjacent to one another and the legs of the trapezoids respectively forming, at least in some places, the first and second side wall portions. This can in particular result in the first side wall portions being inclined by an angle of greater than 90° with regard to the light emitting surface and the second side wall portions being inclined by an angle of smaller than 90° with regard to the light emitting surface, or vice versa, depending on how it is viewed.

According to some embodiments, a lateral distance between opposing first side wall portions increases from the bottom surface into the direction of the light emitting surface and wherein a lateral distance between opposing second side wall portions increases from the light emitting surface into the direction of the bottom surface. In other words, the structure can comprise a cross-section in which a lateral distance between opposing first side wall portions increases from the bottom surface into the direction of the light emitting surface and wherein a lateral distance between opposing second side wall portions increases from the light emitting surface into the direction of the bottom surface. Such a structure can result from respectively stacked trapezoids, triangles, flattened or non-flattened hemispheres, flattened or non-flattened half ellipses, or other shapes that taper from a bottom surface in a direction away from the bottom surface.

According to some embodiments, the light emitting surface is larger than bottom surface. This can again result from the different etching steps as well as the different structures being etched resulting in a differently sized light emitting surface and bottom surface.

According to some embodiments, the semiconductor layer stack comprises a semiconductor material such as for example Indium Gallium Aluminium Phosphide (InGaAlP). The semiconductor layer stack can however also comprise a semiconductor material such as for example Indium Gallium Arsenide (InGaAs), Indium Gallium Nitride (InGaN) just to name some examples. The semiconductor layer stack comprises at least a first layer of a first conductivity type, a second layer of a second conductivity type as well as an active region between the first and second layer. The first layer can for example be a semiconductor layer that is p-doped, whereas the second layer can for example be a semiconductor layer that is n-doped. The two layers can thus form a pn-junction with the active region arranged in-between. The active region can for example comprise a quantum well or multi quantum well structure, or can for example comprise quantum dots.

The light generating structure can in particular be a small light emitting component/element such as a small LED or μLED. A μLED can in particular be a very small LED with edge lengths down to 20 μm, down to 10 μm, down to 5 μm or even less. Such small LEDs require a special handling and processing to improve their IQE and light outcoupling efficiency. One approach to improve the IQE of the μLED is to cover the first side wall portions with a regrowth layer. A possible approach to improve the outcoupling efficiency and light directionality of the light emitted by the μLED is to provide outcoupling structures and/or reflective structures on/in the μLED.

According to some embodiments, the regrowth layer comprises at least one doped or undoped layer of for example a high Al-containing InGaAlP material and an optional additive. The regrowth layer may however also comprise a GaP or GaAs-highly doped contact layer.

According to some embodiments, the bottom contact element is reflective. By means of a reflective bottom contact element, the outcoupling efficiency and light directionality of the light emitted by the μLED can for example be improved, as light generated in the active region gets reflected into a desired direction.

According to a further embodiment, an optoelectronic device is provided. The optoelectronic device can for example be a light emitting device comprising one or more light emitting components such as a small LED or μLED configured to emit light when powered. The optoelectronic device comprises a carrier substrate, a contact layer arranged on the carrier substrate and at least one light generating structure according to one or some of aforementioned embodiments. The bottom contact element of the at least one light generating structure thereby electrically contacts the contact layer such that via the contact layer a first potential can be supplied to the at least one light generating structure.

The optoelectronic device further comprises a reflective structure surrounding the at least one light generating structure in a circumferential direction, wherein the reflective structure exposes at least the light emitting surface and extends from a level below the active region to a level above the light emitting surface. The reflective structure in particular provides a reflector surrounding the at least one light generating structure in circumferential direction, which exposes at least the light emitting surface and extends from a level below the active region to a level above the light emitting surface to reflect light generated within the at least one light generating structure and in particular within the active region of the at least one light generating structure into a desired direction. Due to the fact that the reflective structure extends from a level below the active region to a level above the light emitting surface, the amount of generated light being reflected by the reflective structure is higher compared to a reflective structure extending from the light emitting surface away from the light emitting surface into the direction away from the active region of the at least one light generating structure. The outcoupling efficiency and directionality of emitted light of the optoelectronic device can thus be enhanced.

The optoelectronic device further comprises an isolation layer encapsulating the at least one light generating structure in the circumferential direction and a substantially light transmissive top contact element electrically contacting the second layer of the at least one light generating structure and in particular extending onto the reflective structure. The isolation layer can in particular provide an encapsulation to protect the at least one light generating structure from external influences and at the same time provide an isolation between certain areas of the optoelectronic device to reduce the risk of a short within the optoelectronic device. The top contact element electrically contacting the second layer of the at least one light generating structure on the other hand can in particular provide a contact such that via the top contact element a second potential can be supplied to the at least one light generating structure by means of which the at least one light generating structure can together with the first potential be powered. The top contact element can thereby for example be of a transparent conductive oxide (TCO) such as for example indium tin oxide (ITO) to on the one hand be transmissive for light generated in the at least one light generating structure and on the other hand be conductive to be able to provide the second potential to the at least one light generating structure. The top contact element can be limited to covering the light emitting surface but can also at least partially extend onto the reflective structure, to provide a contact path from the light emitting surface to an outer area of the optoelectronic device.

According to some embodiments, the contact layer follows the shape of the at least one light generating structure and is reflective. The contact layer can for example form a cavity in which the at least one light generating structure is arranged. The contact layer can thus form a reflector for light generated within the at least one light generating structure to reflect light emitted into the direction of the contact layer back into the direction of the light emitting surface. In between the contact layer and the at least one light generating structure, the isolation layer can be arranged except a contact via through the isolation layer to electrically connect the contact layer and the bottom contact element.

According to some embodiments, the reflective structure together with contact layer and/or the bottom contact element of the at least one light generating structure forms a mirror, in particular parabolic-like or parabolic mirror, for light generated in the at least one light generating structure. By means of the combined mirror, light generated within the at least one light generating structure can be outcoupled of the optoelectronic device in an enhanced way, as well as a focusing of the light into a smaller solid angle is possible.

According to some embodiments, the reflective structure is a metallic grid surrounding the at least one light generating structure in the circumferential direction. The reflective structure can in particular be in form of a metallic grid comprising element surrounding the at least one light generating structure in the circumferential direction and comprising bars or residues of bars connecting elements surrounding the at least one light generating structure in the circumferential direction. Due to its conductivity, the metallic grid can together with the top contact element and the contact layer in particular be used to electrically connect the at least one light generating structure to a current source.

According to some embodiments, the isolation layer is arranged between the regrowth layer and/or the bottom contact element of the at least one light generating structure and a portion of the contact layer. This can in particular result from the contact layer having a cavity in which the at least one light generating structure is arranged and the isolation layer being arranged between the at least one light generating structure and the contact layer.

According to some embodiments, the isolation layer is arranged between the second side wall portions of the at least one light generating structure and the reflective structure. This can in particular result from the isolation layer surrounding the at least one light generating structure in the circumferential direction and to avoid a direct contact between the reflective structure and the second side wall portions.

According to some embodiments, the isolation layer is arranged between a portion of the light emitting surface of the at least one light generating structure and the top contact element. The isolation layer can for example partially extend onto the light emitting surface of the at least one light generating structure to limit the electrical contact of the second layer of the at least one light generating structure and the top contact element to a centre of the light emitting surface. By means of this, a current confinement can be achieved to limit the injected current to the centre of the at least one light generating structure. In particular in this case, the isolation layer comprises or is of a light transmissive material, in order to not negatively influence the light extraction from the light emitting surface and thus the optoelectronic device respectively.

According to some embodiments, the isolation layer is of or comprises a reflective material. By means of this an encapsulation of the at least one light generating structure, but not the light emitting surface leads to a maximum possible light emission through the light emitting surface. By means of the reflective structure the light emitted from the light emitting surface can then be formed and directed in a desired way.

According to a further embodiment, a method for manufacturing an optoelectronic device is provided. The optoelectronic device can for example be a light emitting device comprising one or more light emitting components such as a small LED or μLED configured to emit light when powered and can in particular be an optoelectronic device according to one or some of aforementioned embodiments.

The method comprises the steps:
Providing a semiconductor layer stack of at least a first layer of a first conductivity type, a second layer of a second conductivity type as well as an active region between the first and second layer, on a growth substrate;
Structuring the semiconductor layer stack such that the structured semiconductor layer stack comprises a bottom surface and first side wall portions extending from the bottom surface into a direction away from the bottom surface, the first side wall portions comprising portions of the first layer, the second layer and the active region;
Regrowing a regrowth layer on the bottom surface and the first side wall portions;
Providing a bottom contact element on the regrowth layer opposite the bottom surface;
Removing the growth substrate;
Structuring, in particular by means of a low damage mesa etching process, the semiconductor layer stack and/or the regrowth layer from a side different than the previous step of structuring the semiconductor layer stack, resulting in a light emitting surface of the semiconductor layer stack and second side wall portions extending from the light emitting surface into a direction away from the light emitting surface, the second side wall portions comprising portions of the second layer and/or the regrowth layer;
Providing a reflective structure surrounding the semiconductor layer stack in a circumferential direction, wherein the reflective structure exposes at least the light emitting surface and extends from a level below the active region to a level above the light emitting surface; and
Providing a substantially light transmissive top contact element electrically contacting an exposed portion of the second layer and in particular extending onto the reflective structure.

According to some embodiments, the method further comprises at least one of the following steps:
Providing a first isolation layer on the bottom contact element and/or the regrowth layer;
Providing a contact layer on the first isolation layer and an exposed portion of the bottom contact element, electrically contacting the bottom contact element;
Providing a carrier substrate on the contact layer; and Providing a second isolation layer on the light emitting surface and/or the regrowth layer and/or the first isolation layer.

According to some embodiments, the first and second isolation layer together form a combined/single isolation layer, as described for the optoelectronic device according to one or some of aforementioned embodiments.

According to some embodiments, the step of structuring the semiconductor layer stack and/or the step of structuring the semiconductor layer stack and/or the regrowth layer is a mesa etching process, in particular from different sides of the semiconductor layer stack.

According to some embodiments, the method is a method for manufacturing an optoelectronic device according to one or some of aforementioned embodiments. In particular all the features, advantages, configurations and arrangements described for the light generating structure and the optoelectronic device also apply to the method for manufacturing the optoelectronic device and vice versa.

### BRIEF DESCRIPTION OF THE DRAWINGS

Further embodiments in accordance with the proposed principle will become apparent in relation to the various embodiments and examples described in detail in connection with the accompanying drawings in which

FIG. 1 shows a cross sectional view of an optoelectronic device in accordance with some embodiments of the proposed principle; and

FIG. 2A to 12B show steps of two embodiments for manufacturing an optoelectronic device in accordance with some embodiments of the proposed principle.

### DETAILED DESCRIPTION OF ILLUSTRATIVE EMBODIMENTS

The following embodiments and examples disclose various aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the figures can be combined with each other without further ado, without this contradicting the principle according to embodiments of the invention. Some aspects show a regular structure or form. It should be noted that in practice slight differences and deviations from the ideal form may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the figures. So it is possible to deduce such relations between the elements based on the figures.

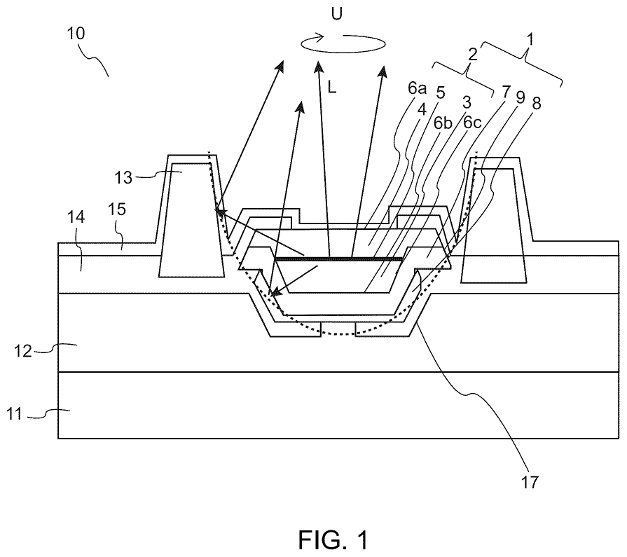

FIG. 1 shows a cross sectional view of an optoelectronic device 10 in accordance with some aspects of the proposed principle. The optoelectronic device 10 comprises a carrier substrate 11 and a contact layer 12 arranged on the carrier substrate 11. Arranged on the contact layer 12 within a cavity 17 of the contact layer 12 and electrically coupled to contact layer 12 is a light generating structure 1.

The light generating structure 1 itself comprises a semiconductor layer stack 2 of a first layer 3 of a first conductivity type, a second layer 4 of a second conductivity type as well as an active region 5 between the first and second layer 3, 4. The semiconductor layer stack 2 is formed such that it comprises a light emitting surface 6a, a bottom surface 6b opposite the light emitting surface 6a and first side wall portions 6c extending from the bottom surface 6b into the direction of the light emitting surface 6a. The first side wall portions 6c thereby comprise portions, in particular side portions of the first layer 3, the second layer 4 and the active region 5.

The light generating structure 1 further comprises a regrowth layer 7 grown on and covering the bottom surface 6b and the first side wall portions 6c and extends in the embodiment shown onto a surface of the second layer 4 adjacent to the first side wall portions 6c. In addition, the light generating structure 1 comprises a bottom contact element 8 arranged on the regrowth layer 7 opposite the first layer 3 and follows the regrowth layer 7 along the first side wall portions 6c more or less encapsulating the regrowth layer 7 in the area of the bottom surface 6b and the first side wall portions 6c.

Besides the first side wall portions 6c of the semiconductor layer stack 2, the light generating structure 1 comprises second side wall portions 9 different from the first side wall portions 6c extending from the light emitting surface 6a into the direction of the bottom surface 6b, the second side wall portions 6c in the embodiment shown comprising portions, in particular side portions, of the regrowth layer 7 and the second layer 4.

Hence, the first side wall portions 6c are formed by the semiconductor layer stack 2, whereas the second side wall portions 9 are formed by the regrowth layer 7 and the second layer 4 or the semiconductor layer stack 2.

An embodiments of the invention now is that the light generating structure 1 is manufactured in such a way that the first side wall portions 6c result from a different etching step than the second side wall portions 9 and in particular of two different etching steps from opposing sides of the semiconductor layer stack 2 resulting in the structure as shown. This structure in combination with later described components has the advantage that an optoelectronic device can be provided by means of which an increased outcoupling efficiency, as well as a focusing of light into a smaller solid angle of light generated in the light generating structure can be achieved. In addition, the mesa structuring from two different sides of the semiconductor layer stack 2 in combination with a later described top contact deposition onto the semiconductor layer stack 2 can enhance internal quantum efficiency (IQE)/reduce nonradiative recombination due to current crowding towards the centre of the semiconductor layer stack 2 from both sides.

Due to the two different etching steps, in particular mesa etching steps the first side wall portions 6c and the second side wall portions 9 are inclined into different directions. In particular, adjacent side wall portions are inclined in different directions so that they are substantially mirror-inverted. The resulting structure is, when viewed in the shown cross section, in the form of two trapezoids arranged one on top of the other, the longer base sides of the trapezoids being adjacent to one another and the legs of the trapezoids respectively forming, at least in some places, the first and second side wall portions 6c, 9. A lateral distance between the opposing first side wall portions 6c thus increases from the bottom surface 6b into the direction of the light emitting surface 6a and a lateral distance between the opposing second side wall portions 9 increases from the light emitting surface 6a into the direction of the bottom surface 6b.

The optoelectronic device 10 further comprises a reflective structure 13 surrounding the at least one light generating structure 1 in a circumferential direction U, wherein the reflective structure 13 exposes the light emitting surface 6a and extends from a level below the active region 5 to a level above the light emitting surface 6a. “Below the active region 5” can for example mean that the reflective structure 13 extends from a level inclusively between the active region 5 and the bottom surface 6b, whereas “above the light emitting surface 6a” can for example mean above the light emitting surface 6a in a direction from the bottom surface 6b to the light emitting surface 6a. Hence the reflective structure 13 protrudes the light generating structure 1 in a direction from the bottom surface 6b to the light emitting surface 6a and protrudes the active region 5 in the opposite direction. By means of this, the amount of generated light L being reflected by the reflective structure 13 is higher compared to a reflective structure extending “only” from the light emitting surface 6a in a direction from the bottom surface 6b to the light emitting surface 6a. The outcoupling efficiency and directionality of emitted light L of the optoelectronic device 10 can thus be enhanced.

The reflective structure 13 is in particular in the form of a ring surrounding the light generating structure 1 with tapered inner side surfaces, to guide/reflect the light generated within the light generating structure 1 in a desired direction. Together with the bottom contact element 8, which in the embodiment shown is of a reflective material, the reflective structure 13 forms a mirror structure, guiding/reflecting the light generated within the light generating structure 1 in a desired direction. The mirror structure as well as the reflection of light L is indicated in FIG. 1 by means of the dotted half ellipse and the reflected arrows indicative of the reflected light L.

The light generating structure 1 in total and the reflective structure 13 partially are embedded in an isolation layer 14. The isolation layer 14 encapsulates the light generating structure 1 in the circumferential direction U and extends partially onto the light emitting surface 6a as well as onto the bottom contact element 8 opposite the bottom surface 6b. The isolation on the one hand holds all components in place, protects the light generating structure 1 from external influences and prevents a short within the optoelectronic device 10. As the isolation layer 14 extends partially onto the light emitting surface 6a, the isolation layer is of a light transmissive material, at least for the light generated within the active region 5 of the light generating structure 1.

For electrically contacting, the optoelectronic device 10 comprises besides the contact layer 12 a substantially light transmissive top contact element 15 electrically contacting the second layer 4 of the light generating structure 1. The top contact element 15 can for example comprise ITO and be configured to provide an electrical potential to the second layer 4 of the light generating structure 1. In the embodiment shown, the top contact element 15 not only covers the light emitting surface 6a but extends onto the reflective structure 13 as well. By means of this the top contact element 15 can be electrically contacted outside the light emitting area, to not negatively influence the outcoupling efficiency of the optoelectronic device at a later point.

The embodiment shown shows only a single light generating structure 1 comprised in the optoelectronic device 10, however one optoelectronic device 10 can also comprise several light generating structures 1 next to each other, being surrounded by a single reflective structure 13 or each being surrounded by a separate reflective structure 13. For example, it is conceivable that three light generating structures 1 are surrounded by one reflective structure 13, wherein the three light generating structures 1 are configured to emit red, green and blue light together forming an RGB pixel. It is for example also conceivable that several similar light generating structures 1 are provided and surrounded by a single reflective structure 13, to either provide brighter light of a respective wavelength or to provide a “backup” light generating structure in case the other light generating structure(s) 1 is damaged. This is however only to be understood exemplary and the number of light generating structures 1 can be chosen differently as well as the wavelength of light being emitted by the light generating structures 1. Also, the electrical contacting of several light generating structures 1 can vary in such that all or some of the light generating structures 1 can be operated individually and/or all or some of the light generating structures 1 can be connected such that they are simultaneously operated.

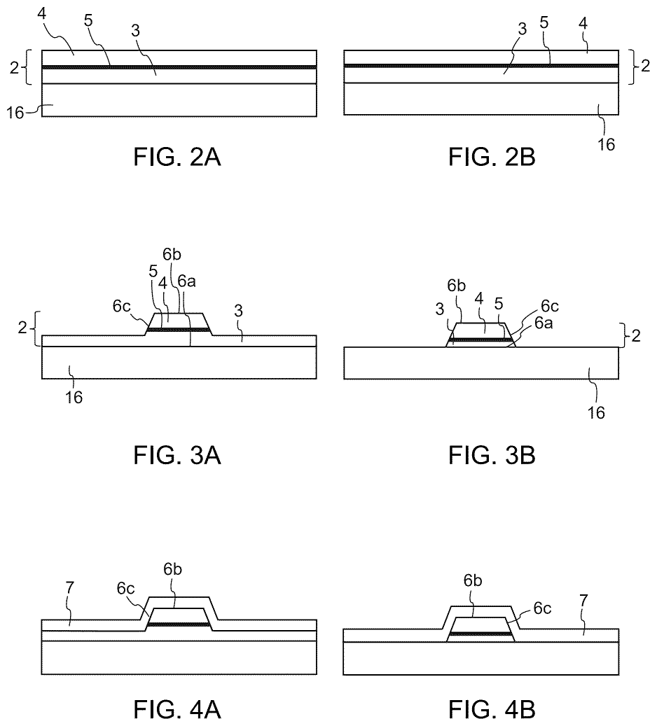

FIG. 2A to 12B show steps of two embodiments for manufacturing an optoelectronic device in accordance with some aspects of the proposed principle. Figures “X”A thereby show a first embodiment of steps of a method for manufacturing an optoelectronic device in accordance with some aspects of the proposed principle whereas Figures “X”B show a second embodiment of steps of a method for manufacturing an optoelectronic device in accordance with some aspects of the proposed principle. The variable “X” thereby stands for the number 2 to 12.

In a first step, as shown in FIG. 2A an 2B, a growth substrate 16 is provided with a semiconductor layer stack 2 epitaxially grown on top. The semiconductor layer stack 2 comprises a first layer 3 of a first conductivity type, a second layer 4 of a second conductivity type as well as an active region 5 between the first and second layer 3, 4.

In a second step, as shown in FIGS. 3A and 3B, a first mesa etching step is performed. The first mesa etching step structures the semiconductor layer stack 2, resulting in exposed portions of the semiconductor layer stack 2 that include a bottom surface 6b and inclined first side wall portions 6c. The etching, as shown in FIG. 3A compared to FIG. 3B is performed such that the etching does not go through the whole second layer 4 but stops well before reaching the growth substrate 16. The etching, as shown in FIG. 3B on the other hand is performed such that the etching goes through the whole second layer 4 and stops when reaching the growth substrate 16. The exposed portions are thereby as shown in cross section in form of trapezoids arranged on a residue of the second layer 4 in case of FIG. 3A or arranged on the growth substrate 16 as shown in FIG. 3B.

In a following step, as shown in FIGS. 4A and 4B, a regrowth layer 7 is regrown on the mesa etched structure and following the shape of the mesa etched structure. The regrowth layer 7 is regrown such that it covers at least the bottom surface 6b as well as the first side wall portions 6c. The regrowth layer 7 can for example be grown by means of a MOVPE-Epitaxy process. Besides the bottom surface 6b as well as the first side wall portions 6c, the regrowth layer 7 also covers the residue of the second layer 4 in case of FIG. 4A or the growth substrate 16 adjacent to the first side wall portions 6c as shown in FIG. 4B. The regrowth layer 7 can for example comprise a thickness between 30 nm to 400 nm.

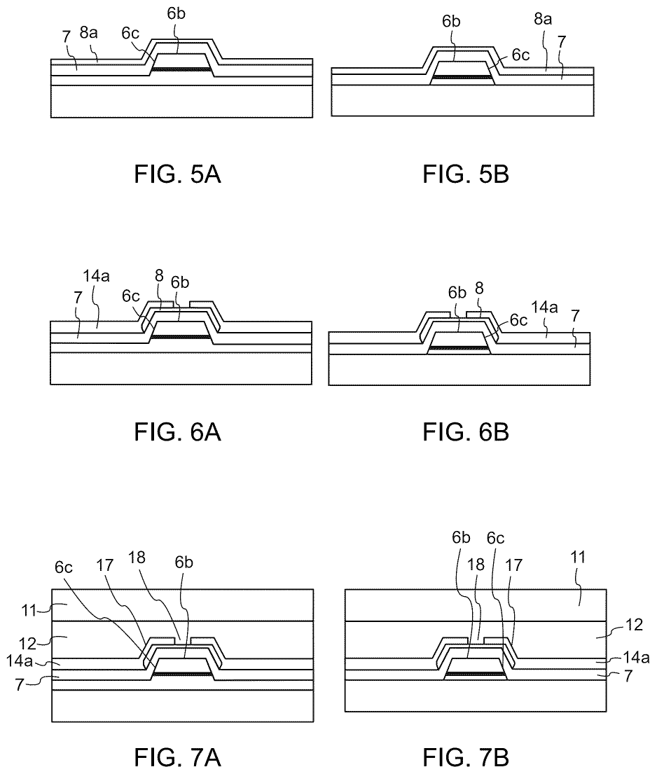

FIGS. 5A and 5B show a subsequent step of providing a bottom contact layer 8a on the regrowth layer 7 following the shape of the regrowth layer 7. The bottom contact layer 8a is a conductive layer and can be for example of a metal or a TCO such as ITO. The bottom contact layer 8a can for example be sputtered, spined, or sprayed on the regrowth layer 7 and can for example comprise a metal oxide like ITO, or a material like ZnO, Au, AuGe, or Ag. In the embodiments shown, the bottom contact layer 8a is provided all over the regrowth layer 7 and in a subsequent step structured to form the later bottom contact element 8, however it is also conceivable to provide the bottom contact layer 8a already structured on the regrowth layer 7 to form the later bottom contact element 8.

In a following step, as shown in FIGS. 6A and 6B, a first isolation layer 14a is provided on the structured bottom contact layer 8a as well as on the regrowth layer 7 covering the top side of the existing structure following the shape of the existing structure. The first isolation layer 14 can for example comprise Al2O3, SiO2, SiNx, or Nb2O5 and can for example be applied by means of CVD, PVD or ALD. In the embodiments shown, the first isolation layer 14a is provided all over top side of the existing structure (structured bottom contact layer 8a & regrowth layer 7) and in a subsequent step structured to expose a portion of the bottom contact element 8. It is however also conceivable to provide the first isolation layer 14a already structured on the existing structure to expose a portion of the bottom contact element 8.

As shown in FIGS. 7A and 7B, a contact layer 12 is then provided on the first isolation layer 14a contacting the exposed portion of the bottom contact element 8. The contact layer 12 follows the shape of the first isolation layer 14a on its side facing the first isolation layer 14a and forms a substantially flat surface on a side opposite the first isolation layer 14a. On this substantially flat surface a carrier substrate 11 is then provided.

As the contact layer 12 follows the shape of the first isolation layer 14a on its side facing the first isolation layer 14a, the contact layer 12 forms a cavity 17 in which the mesa etched portion of the semiconductor layer stack 2 is arranged. The contact layer 12 is of a conductive and in particular of a reflective material to on the one hand provide an electrical connection to the bottom contact element and on the other hand form a back side mirror for the semiconductor layer stack 2. The cavity 17 thereby helps to reflect light generated within the semiconductor layer stack 2 in a guided manner into a desired direction. The contact layer 12 can for example comprise a solder material on which the carrier layer 11 is then bonded. The carrier layer can for example be or comprise an integrated circuit.

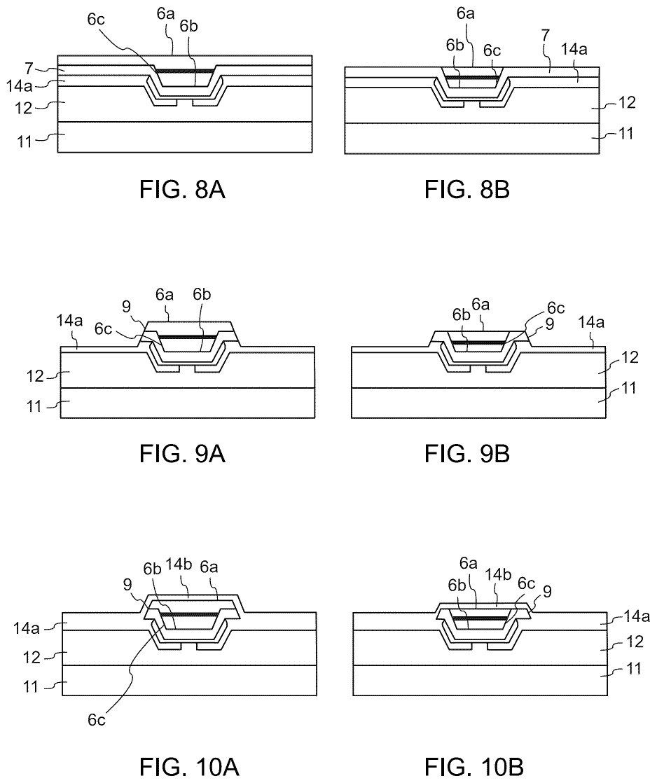

In a subsequent step, as shown in FIGS. 8A and 8B, the growth substrate 16 is removed. For this purpose, the structure can be turned over to remove the growth substrate 16 so that the surface thus exposed faces upwards in order to be able to process the structure from the side of the exposed surface. Due to the removal of the growth substrate 16 a surface of the semiconductor layer stack 2 later forming the light emitting surface 6a of a light generating structure within the optoelectronic device is exposed.

The growth substrate 16 removal is then followed by a second mesa etching step as shown in FIGS. 9A and 9B. The second mesa etching step structures in case of FIG. 9A the residue of the second layer 4 as well as the regrowth layer 7 and in case of FIG. 9B only the regrowth layer 7, resulting in inclined second side wall portions 9. The etching, as shown in FIG. 9A compared to FIG. 9B is performed such that the etching goes through the residue of the second layer 4 as well as the regrowth layer 7 and stops when reaching the first isolation layer 14a. The etching, as shown in FIG. 9B on the other hand is performed such that the etching goes through the regrowth layer 7 and stops when reaching the first isolation layer 14a. The exposed portions are thereby as shown in cross section in form of larger and mirrored trapezoids arranged on the existing trapezoids of the semiconductor layer stack 2. Hence the second etching step from a different direction than the first etching step generates a structure which resembles in the shown cross section a diamond or kite with flattened upper and lower tips. The resulting structure can thereby, not only because of the inclined side wall portions into different directions but also due to the lateral offset between the side walls, only be manufactured by means of the described technique, namely an etching from two different sides of the semiconductor layer stack 2.

Due to the second etching step, a light generating structure within the optoelectronic device is created, with the light generating structure comprising the structured semiconductor layer stack 2, the structured regrowth layer 7 as well as the bottom contact element 8.

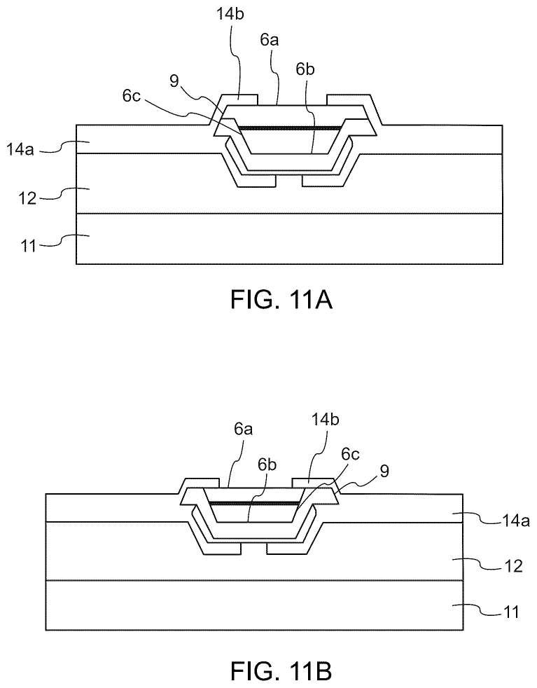

In a following step, as shown in FIGS. 10A and 10B, a second isolation layer 14b is provided on the first isolation layer 14a as well as on the light generating structure covering the top side of the existing structure following the shape of the existing structure. The second isolation layer 14b can for example comprise Al2O3, SiO2, SiNx, or Nb2O5 and can for example be applied by means of CVD, PVD or ALD. In the embodiments shown, the second isolation layer 14b is provided all over top side of the existing structure (first isolation layer 14a & light generating structure) and in a subsequent step, as shown in FIGS. 11A and 11B, structured to expose a portion of the light emitting surface 6a. It is however also conceivable to provide the second isolation layer 14b already structured on the existing structure to expose a portion of the light emitting surface 6a. The first and second isolation layer 14a, 14b are in particular of the same material and together form a common isolation layer 14.

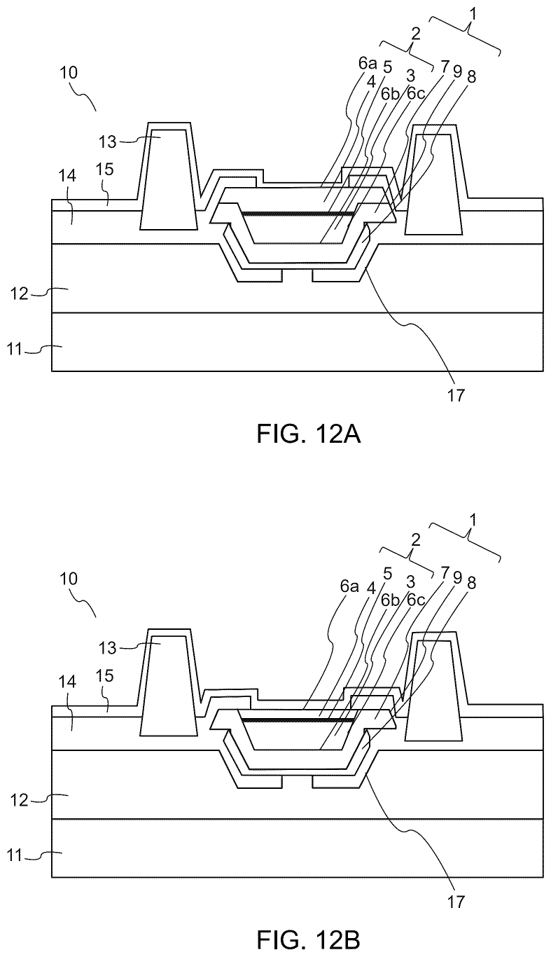

In a subsequent step, as shown in FIGS. 12A and 12B, a reflective structure 13 is then provided surrounding the light generating structure 1 in a circumferential direction, wherein the reflective structure 13 exposes the light emitting surface 6a and extends from a level below the active region 5 to a level above the light emitting surface 6a. The isolation layer can therefore for example be structured to provide respective cavities in which the reflective structure 13 is then arranged. Further, a substantially light transmissive top contact element 15 is provided electrically contacting the second layer 4 of the light generating structure 1 extending all over the existing structure and onto the reflective structure 13. The top contact element 15 can for example be of a TCO such as ITO, to provide an electric top contact for the light generating structure 1. The resulting structure forms an optoelectronic device 10 in accordance with some aspects of the proposed principle.

In the embodiments shown in FIGS. 2A to 12B, exemplary only one optoelectronic device 10 is each shown. It is however to be understood that the method for manufacturing can comprises the manufacturing of a whole wafer of optoelectronic devices 10 arranged on the wafer next to each other at a time in the same way as described. The reflective structure 13 can then for example be in form of a grid provided all over the wafer, wherein the grid comprises elements surrounding the light generating structures 1 in a circumferential direction as shown in FIGS. 12A and 12B and with bars in-between the elements holding the elements in place.

1.-18. (canceled)

19. A light generating structure comprising:
a semiconductor layer stack of at least a first layer of a first conductivity type, a second layer of a second conductivity type, and an active region between the first and second layers, the semiconductor layer stack comprising a light emitting surface, a bottom surface opposite the light emitting surface and first side wall portions extending from the bottom surface into a direction of the light emitting surface, wherein the first side wall portions comprise portions of the first layer, the second layer and the active region;
a regrowth layer covering at least the bottom surface and the first side wall portions;
a bottom contact element arranged on the regrowth layer opposite the first layer; and
second side wall portions different from the first side wall portions extending from the light emitting surface into a direction of the bottom surface, the second side wall portions comprising at least portions of the regrowth layer,
wherein the first side wall portions and the second side wall portions are inclined into different directions.

20. The light generating structure according to claim 19, wherein the second side wall portions comprise portions of the second layer.

21. The light generating structure according to claim 19, wherein adjacent first side wall portions and second side wall portions are laterally distant from each other.

22. The light generating structure according to claim 19, wherein the first side wall portions and/or the second side wall portions are inclined.

23. The light generating structure according to claim 19,
wherein a lateral distance between opposing first side wall portions increases from the bottom surface into the direction of the light emitting surface, and
wherein a lateral distance between opposing second side wall portions increases from the light emitting surface into the direction of the bottom surface.

24. The light generating structure according to claim 19, wherein the light emitting surface is larger than the bottom surface.

25. The light generating structure according to claim 19, wherein the regrowth layer comprises a highly doped semiconductor material.

26. The light generating structure according to claim 19, wherein the bottom contact element is reflective.

27. An optoelectronic device manufactured according to claim 19.

28. An optoelectronic device comprising:
a carrier substrate;
a contact layer arranged on the carrier substrate;
at least one light generating structure according to claim 19 arranged on the contact layer, wherein the bottom contact element of the at least one light generating structure electrically contacts the contact layer;
a reflective structure surrounding the at least one light generating structure in a circumferential direction, wherein the reflective structure exposes at least the light emitting surface and extends from a level below the active region to a level above the light emitting surface;
an isolation layer encapsulating the at least one light generating structure in the circumferential direction; and
a light transmissive top contact element electrically contacting the second layer of the at least one light generating structure.

29. The optoelectronic device according to claim 28, wherein the contact layer follows a shape of the at least one light generating structure.

30. The optoelectronic device according to claim 28, wherein the reflective structure together with the contact layer and/or the bottom contact element of the at least one light generating structure forms a mirror.

31. The optoelectronic device according to claim 28, wherein the reflective structure is a metallic grid surrounding the at least one light generating structure in the circumferential direction.

32. The optoelectronic device according to claim 28,
wherein the isolation layer is arranged between the regrowth layer and/or the bottom contact element of the at least one light generating structure and the contact layer, and/or
wherein the isolation layer is arranged between the second side wall portions of the at least one light generating structure and the reflective structure, and/or
wherein the isolation layer is arranged between a portion of the light emitting surface of the at least one light generating structure and the top contact element.

33. The optoelectronic device according to claim 28, wherein the isolation layer is substantially light transmissive.

34. A method for manufacturing an optoelectronic device, the method comprising:
providing a semiconductor layer stack of at least a first layer of a first conductivity type, a second layer of a second conductivity type, and an active region between the first and second layers, on a growth substrate;
first structuring the semiconductor layer stack such that the structured semiconductor layer stack comprises a bottom surface and first side wall portions extending from the bottom surface in a direction away from the bottom surface, the first side wall portions comprising portions of the first layer, the second layer and the active region;
regrowing a regrowth layer on the bottom surface and the first side wall portions;
providing a bottom contact element on the regrowth layer opposite the bottom surface;
removing the growth substrate;
second structuring the semiconductor layer stack and/or the regrowth layer from a side different than the first structuring of the semiconductor layer stack, resulting in a light emitting surface of the semiconductor layer stack and second side wall portions extending from the light emitting surface into a direction of the bottom surface, the second side wall portions comprising portions of the second layer and/or the regrowth layer;
providing a reflective structure surrounding the semiconductor layer stack in a circumferential direction, wherein the reflective structure exposes at least the light emitting surface and extends from a level below the active region to a level above the light emitting surface; and
providing a light transmissive top contact element electrically contacting an exposed portion of the second layer.

35. The method according to claim 34, further comprising:
providing a first isolation layer on the bottom contact element and/or the regrowth layer;
providing a contact layer on the first isolation layer and an exposed portion of the bottom contact element, electrically contacting the bottom contact element;
providing a carrier substrate on the contact layer; and
providing a second isolation layer on the light emitting surface and/or the regrowth layer and/or the first isolation layer.

36. The method according to claim 34, wherein first and second structuring the semiconductor layer stack and/or regrowing the regrowth layer is a mesa etching process.
